(19) United States
(12) Patent Application Publication
(10) Pub. No.: US 2026/0282792 A1
(43) Pub. Date: Sep. 17, 2026

(54) INTERLOCK SYSTEM, SUBSTRATE PROCESSING APPARATUS, INTERLOCK DISPLAY METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Masafumi KONISHI, Toyama-shi (JP)

(73) Assignee: Kokusai Electric Corporation, Tokyo (JP)

(21) Appl. No.: 19/668,428

(22) Filed: May 5, 2026

Related U.S. Application Data
(63) Continuation of application No. PCT/JP2023/046692, filed on Dec. 26, 2023.

(51) Int. Cl. H10P 72/00

(52) U.S. Cl. CPC H10P 72/0402

(57) ABSTRACT

It is possible to easily identify a location causing or likely to cause the interlock. There is provided a technique that includes: detectors in modules constituting a substrate processing apparatus, for detecting physical states thereof to output detection signals therefor; an interlock determination processor storing interlock conditions establishing interlocks to determine whether each interlock is established based on the detection signals; and a display controller for graphically displaying, on a display, a module corresponding to a first factor establishing an interlock in a case where the interlock is established or corresponding to a second factor preventing the interlock from being established in a case where the interlock occurs if a physical state satisfies a condition among the interlock conditions corresponding thereto, such that the module is recognizable on an image indicating a structure of the substrate processing apparatus.

### CROSS-REFERENCE TO RELATED PATENT APPLICATION

This application is a bypass continuation application of PCT International Application No. PCT/JP2023/046692, filed on Dec. 26, 2023, in the WIPO, the entire contents of which are hereby incorporated by reference.

### BACKGROUND

### 1. Field

The present disclosure relates to an interlock system, a substrate processing apparatus, an interlock display method, a method of manufacturing a semiconductor device and a non-transitory computer-readable recording medium.

### 2. Related Art

According to some related arts, when a gas sensor detects a gas leak during a manufacturing process of a semiconductor device, an interlock operation corresponding to the gas leak may be performed.

### SUMMARY

According to the present disclosure, there is provided a technique capable of easily identifying a location causing an interlock or a location likely to cause the interlock.

According to the embodiments of the present disclosure, there is provided a technique that includes: detectors respectively provided in a plurality of modules constituting a substrate processing apparatus, configured to detect physical states of the substrate processing apparatus and configured to output detection signals indicating the physical states; an interlock determination processor configured to store preset interlock conditions establishing a plurality of interlocks, respectively, and configured to determine whether or not each of the plurality of interlocks is established based on the detection signals from the detectors; and a display controller configured to be capable of graphically displaying, on a display, a module corresponding to a first factor establishing an interlock among the plurality of interlocks in a case where the interlock is established or corresponding to a second factor preventing the interlock from being established in a case where the interlock occurs if a physical state among the physical states satisfies a condition among the interlock conditions corresponding thereto, such that the module is recognizable on an image indicating a structure of the substrate processing apparatus.

### BRIEF DESCRIPTION OF THE DRAWINGS

FIG. 1 is a diagram schematically illustrating a perspective view of an example of a substrate processing apparatus according to one or more embodiments of the present disclosure.

FIG. 2 is a diagram schematically illustrating a perspective view of the substrate processing apparatus according the embodiments of the present disclosure when viewed from rear.

FIG. 3 is a block diagram schematically illustrating an example of a control configuration (that is, a controller and its related components) of the substrate processing apparatus according the embodiments of the present disclosure.

FIG. 4 is a diagram schematically illustrating an example of an interlock condition table stored in a memory according the embodiments of the present disclosure.

FIG. 5 is a diagram schematically illustrating an example of an interlock display position table stored in the memory according the embodiments of the present disclosure.

FIG. 6 is a flow chart schematically illustrating an interlock display process of the substrate processing apparatus according to the embodiments of the present disclosure.

FIG. 7 is a diagram schematically illustrating an example of a display screen of a display according to the embodiments of the present disclosure.

FIG. 8 is a diagram schematically illustrating another example of the display screen of the display according to the embodiments of the present disclosure.

FIG. 9 is a diagram schematically illustrating a modified example of the display screen of the display according to the embodiments of the present disclosure.

### DETAILED DESCRIPTION

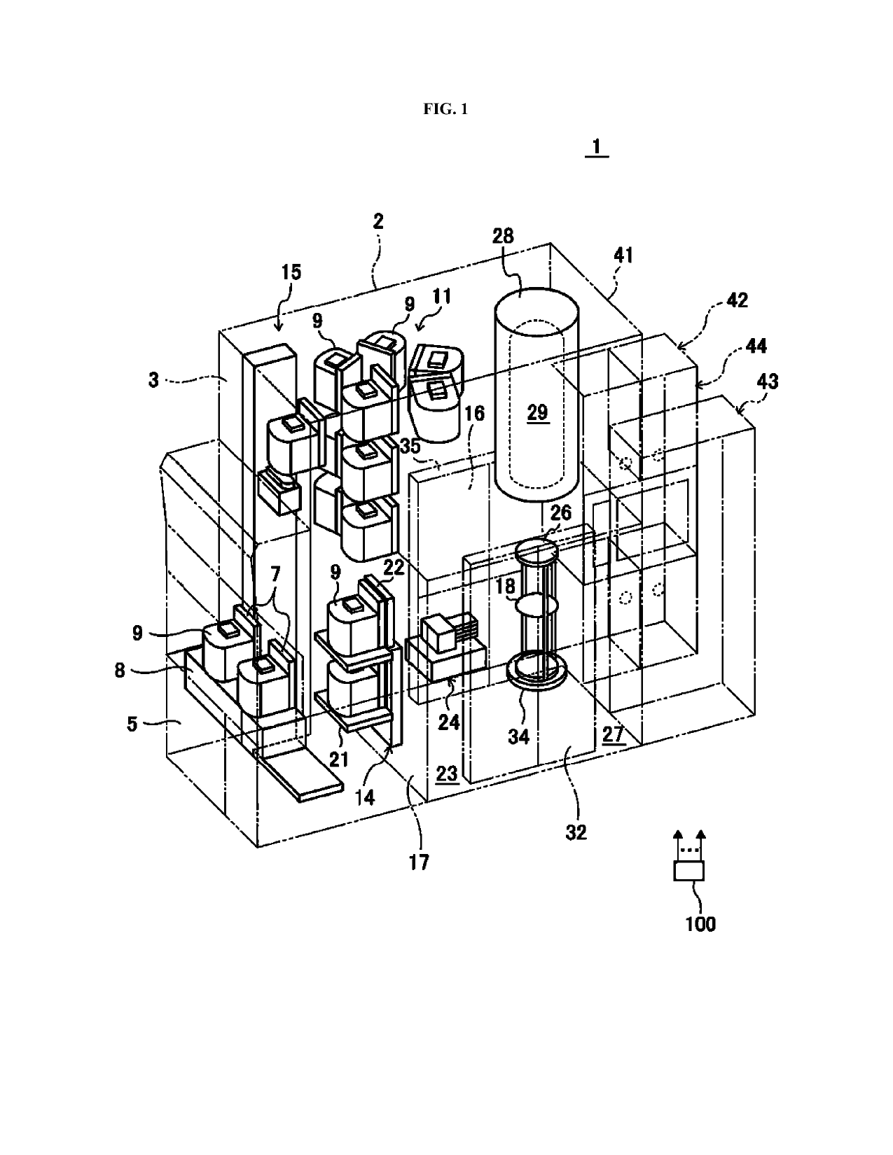

Hereinafter, one or more embodiments (also simply referred to as “embodiments”) according to the technique of the present disclosure will be described mainly with reference to FIGS. 1 to 8. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the technique of the present disclosure is not limited to the embodiments described below. That is, the technique of the present disclosure may be appropriately modified in various ways without departing from the scope thereof.

Further, in the following description, the term “worker” (or operator) refers to a person who uses a substrate processing apparatus or a person who processes a substrate using the substrate processing apparatus.

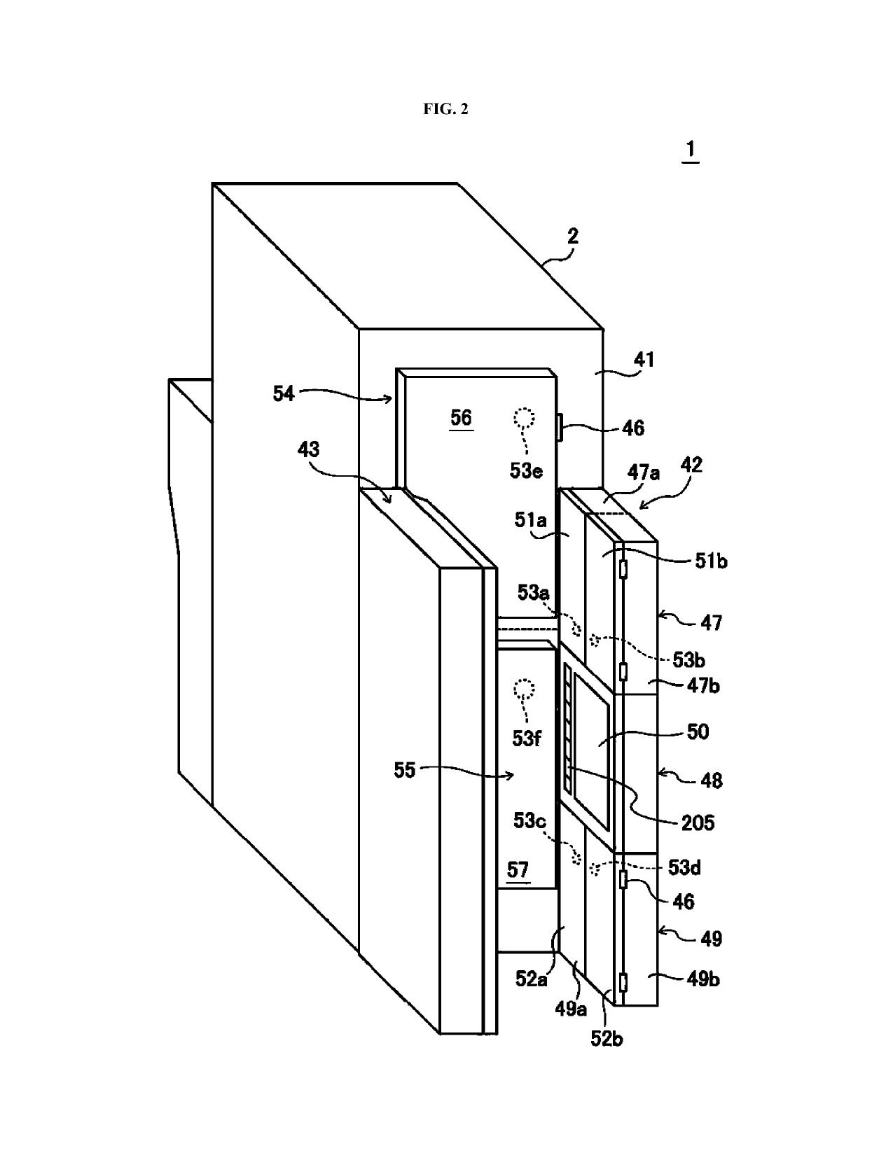

First, with reference to FIGS. 1 and 2, an outline of a substrate processing apparatus 1 according to the present embodiments will be described.

FIG. 1 is a diagram schematically illustrating a perspective view of an example of the substrate processing apparatus 1 according to the present embodiments, and FIG. 2 is a diagram schematically illustrating a perspective view of the substrate processing apparatus 1 according to the present embodiments when viewed from rear. In FIGS. 1 and 2, a vertical type substrate processing apparatus is shown as an example of the substrate processing apparatus 1.

As shown in FIGS. 1 and 2, the substrate processing apparatus 1 includes a housing 2. An opening for maintenance is provided at a lower portion of a front wall 3 of the housing 2. The opening can be opened or closed by a front maintenance door 5.

A pod loading/unloading port is provided at the front wall 3 of the housing 2 so as to communicate between an inside (inner portion) and an outside (outer portion) of the housing 2. The pod loading/unloading port can be opened or closed by a front shutter (which is a pod loading/unloading port opening/closing structure) 7. A loading port (which is a loading port shelf, that is, a transfer table for a substrate transfer container) 8 is provided in front of the pod loading/unloading port. The loading port 8 is configured such that a pod 9 is aligned while placed on the loading port 8.

For example, the pod 9 is configured as a sealed type substrate transfer container. The pod 9 can be transferred (loaded) into and placed on the loading port 8 by an in-process transfer apparatus (not shown) and can be transferred (unloaded) out of the loading port 8 by the in-process transfer apparatus.

A rotatable pod shelf (which is a storage shelf for the substrate transfer container) 11 is provided in the housing 2 to be located over a substantially center portion of the housing 2 in a front-rear direction. The rotatable pod shelf 11 is configured such that a plurality of pods including the pod 9 can be stored (or placed) on the rotatable pod shelf 11. Hereinafter, the plurality of pods including the pod 9 may also be simply referred to as “pods 9”.

A pod opener (which is a structure capable of opening and closing a lid of the substrate transfer container) 14 is provided below the rotatable pod shelf 11. The pod opener 14 is provided with a configuration on which the pod 9 is placed and capable of opening and closing the lid of the pod 9.

A pod transfer structure (which is a container transfer structure) 15 is provided among the loading port 8, the rotatable pod shelf 11 and the pod opener 14. The pod transfer structure 15 is configured such that the pod 9 can be elevated and lowered and can be moved forward and backward in a horizontal direction while being supported by the pod transfer structure 15. The pod transfer structure 15 is further configured such that the pod 9 can be transferred among the loading port 8, the rotatable pod shelf 11 and the pod opener 14.

A sub-housing 16 is provided below the substantially center portion of the housing 2 in the front-rear direction to extend toward a rear end of the substrate processing apparatus 1. A pair of wafer loading/unloading ports (which are substrate loading/unloading ports) through which a wafer 18 serving as a substrate is loaded into or unloaded out of the sub-housing 16 is provided at a front wall 17 of the sub-housing 16. The pair of wafer loading/unloading ports is arranged vertically in two stages. A pair of pod openers (including the pod opener 14) is provided at the pair of wafer loading/unloading ports, respectively. For example, an upper pod opener and a lower pod opener may be provided as the pair of pod openers. The upper pod opener and the lower pod opener may be collectively or individually referred to as the “pod opener 14”.

The pod opener 14 may include: a mounting table (which is a placement table) 21 where the pod 9 is placed thereon; and an opening/closing structure 22 capable of attaching and detaching the lid of the pod 9. The pod opener 14 is configured such that a wafer entrance of the pod 9 is opened or closed by opening (or detaching) or closing (or attaching) the lid of the pod 9 placed on the mounting table 21 by the opening/closing structure 22.

The sub-housing 16 defines a transfer chamber 23 fluidically isolated from a space (hereinafter, also referred to as a “pod transfer space”) in which the pod transfer structure 15 or the rotatable pod shelf 11 is provided. A wafer transfer structure (which is a substrate transfer structure) 24 is provided at a front region of the transfer chamber 23. The wafer transfer structure 24 is configured such that the wafer 18 can be loaded into or unloaded out of a boat 26 serving as a substrate retainer.

In a rear region of the transfer chamber 23, a standby space 27 where the boat 26 is accommodated and in standby is provided, and a process furnace 28 such as a vertical type process furnace is provided above the standby space 27. A process chamber 29 is provided inside the process furnace 28, and a lower end portion of the process chamber 29 is configured as a furnace opening. The furnace opening is opened or closed by a furnace opening shutter. The process furnace 28 serves as an example of a process vessel in which the wafer 18 is processed.

A boat elevator (which is a substrate retainer elevating structure) 32 capable of elevating and lowering the boat 26 is provided below the process furnace 28. A seal cap 34 serving as a lid is horizontally attached to the boat elevator 32. The seal cap 34 is configured such that the boat 26 can be vertically supported by the seal cap 34, and such that the furnace opening can be airtightly closed by the seal cap 34 while the boat 26 is loaded into the process chamber 29.

The boat 26 is configured such that a plurality of wafers (for example, from 50 wafers to 125 wafers) including the wafer 18 are supported on the boat 26 in a horizontal orientation in a multistage manner with their centers aligned with one another. Hereinafter, the plurality of wafers including the wafer 18 may also be simply referred to as “wafers 18”. Further, in the present specification, a notation of a numerical range such as “from 50 wafers to 125 wafers” means that a lower limit and an upper limit are contained in the numerical range. Therefore, for example, a numerical range “from 50 wafers to 125 wafers” means a range equal to or higher than 50 wafers and equal to or less than 125 wafers. The same also applies to other numerical ranges described in the present specification.

A clean air supplier (which is a clean air supply structure or a clean air supply system) 35 is arranged at a position facing the boat elevator 32. The clean air supplier 35 is constituted by a supply fan and a dustproof filter so as to supply clean air such as a clean atmosphere and an inert gas.

A utility structure 42 and an exhaust structure 43 are provided at a rear wall 41 of the housing 2 such that a side surface of the utility structure 42 and a side surface of the exhaust structure 43 are provided continuously with side surfaces of the housing 2, respectively. The utility structure 42 and the exhaust structure 43 are arranged facing each other. A maintenance space (also referred to as a “maintenance and inspection space”) 44 is provided (or formed) between the utility structure 42 and the exhaust structure 43. The maintenance space 44 is a space where a worker (also referred to as an “operator”) can perform a maintenance operation and an inspection operation for the substrate processing apparatus 1. The utility structure 42 is used as a utility portion of the substrate processing apparatus 1. In the exhaust structure 43, a component such as an exhaust assembly configured to exhaust an atmosphere (inner atmosphere) of the housing 2 can be accommodated.

The utility structure 42 is divided into three portions in a height direction. An upper portion of the utility structure 42 is used as a gas box 47, a middle portion of the utility structure 42 is used as a control box 48, and a lower portion of the utility structure 42 is used as a gas box 49.

In the control box 48, a process controller 205 configured to control the substrate processing apparatus 1 and a subsidiary operation panel (which is a secondary operation panel) 50 operated by the worker are provided. The subsidiary operation panel 50 may be used as a display (which is a display structure) 204 configured to display a physical state of the substrate processing apparatus 1 and a manipulator 203 configured to operate the substrate processing apparatus 1.

The gas box 47 is divided into two halves (that is, a left portion and a right portion). For example, the gas box 47 is divided into modules 47a and 47b from the rear wall 41. Doors (which can be opened and closed) 51a and 51b are provided at front walls of the modules 47a and 47b, respectively. The doors 51a and 51b are configured to be capable of being opened and closed by using connecting structures 46 (such as hinges) mounted externally thereon as pivots. In the modules 47a and 47b, for example, components such as a gas supply assembly for a gaseous source material and/or a carrier gas, a gas flow rate controller 208, piping, a valve and the like related thereto can be accommodated.

The gas box 49 is divided into two halves (that is, a left portion and a right portion). For example, the gas box 49 is divided into modules 49a and 49b from the rear wall 41. Doors (which can be opened and closed) 52aand 52b are provided at front walls of the modules 49a and 49b, respectively. The doors 52a and 52b are configured to be capable of being opened and closed by using connecting structures 46 mounted externally thereon as pivots. In the modules 49a and 49b, for example, components such as a tank for a liquid source material, a vaporizer, a gas flow rate controller 208, piping, a valve and the like related thereto can be accommodated.

In other words, the utility structure 42 is constituted by a plurality of modules, that is, the modules 47a, 47b, 49a and 49b (which are divided portions of the utility structure 42) and the control box 48. The worker can open the doors 51a, 51b, 52a and 52b on the modules 47a, 47b, 49a and 49b to perform the maintenance operation on a gas supply system including the components such as the gas supply assembly for the gaseous source material and/or the carrier gas, the gas flow rate controller 208, the piping, the valve and the like related thereto and the components such as the tank for the liquid source material, the vaporizer, the gas flow rate controller 208, the piping, the valve and the like related thereto.

The rear wall 41 of the housing 2 is divided into two portions (that is, an upper portion and a lower portion). For example, the rear wall 41 is divided into modules 54 and 55 from an upper end thereof. Maintenance and inspection ports are provided at the modules 54 and 55, respectively. Doors 56 and 57 are provided at the maintenance and inspection ports, respectively. The doors 56 and 57 are configured to be capable of being opened and closed by using connecting structures 46 mounted adjacent to the utility structure 42 of the rear wall 41 (a right side in FIG. 2).

Sensors 53a, 53b, 53c, 53d, 53e and 53f are provided inside the doors 51a, 51b, 52a, 52b, 56 and 57 of the modules 47a, 47b, 49a, 49b, 54 and 55, respectively. The sensors 53a to 53f serve as detectors configured to detect open/closed states of the doors 51a, 51b, 52a, 52b, 56 and 57 and configured to output detection signals, respectively. In addition to the sensors 53a to 53f, each of the modules 47a, 47b, 49a, 49b, 54 and 55 is also provided with a first group of sensors (that is, a first sensor group) configured to detect open/closed states of the valves of the modules 47a, 47b, 49a, 49b, 54 and 55 and the physical state of the substrate processing apparatus 1, such as a pressure sensor, a temperature sensor, a flow rate sensor and a liquid leak sensor, and configured to output detection signals.

When processing the wafer 18 in the substrate processing apparatus 1, various types of chemical substances are used. The chemical substances are classified into flammable, combustion-stimulating, toxic, corrosive and the like, and an allowable exposure concentration is set for each chemical substance. Therefore, the gas supply system such as the piping is accommodated in the gas boxes 47 and 49, and the first sensor group and the like installed in each of the modules 47a, 47b, 49a and 49b are configured to detect a gas leak and the like and configured to activate (or operate) an interlock.

In the present specification, the term “interlock” (hereinafter, also referred to as an “ILK”) refers to a safety arrangement implemented using a ladder program in a programmable logic controller (PLC) to prevent an inappropriate setting or an operation error in an apparatus such as the substrate processing apparatus 1.

According to the present embodiments, the ILK is activated by detecting the open/closed states of the doors 51a, 51b, 52a, 52b, 56 and 57, the open/closed states of the valves of the modules 47a, 47b, 49a, 49b, 54 and 55 and the physical state such as a pressure, a temperature, a flow rate and a liquid leak using the first sensor group and the like provided in each of the modules 47a, 47b, 49a, 49b, 54 and 55. In addition, each of the module 47a, 47b, 49a, 49b, 54 and 55 is partitioned such that the sensor that causes the ILK to activate and a location that is the actual factor of the ILK (which will be described in detail later) are arranged in the same module.

For example, to prevent a simultaneous opening of valves (for gases) that may cause an unintended reaction when the gases are mixed, the ILK is activated by detecting the open/closed states of the valves (for gases). In addition, by using each sensor provided in the modules 54 and 55, the ILK is set to operate to prevent the doors 56 and 57 from being opened accidentally when the process furnace 28 is in a high temperature state, or while the wafer 18 is being processed in the process furnace 28, or while the wafer 18 is being transferred in the transfer chamber 23.

Subsequently, an operation of the substrate processing apparatus 1 will be described.

When the pod 9 is supplied to the loading port 8, the pod loading/unloading port is opened by the front shutter 7. Then, the pod 9 placed on the loading port 8 is transferred (loaded) into the housing 2 by the pod transfer structure 15, and is placed on the rotatable pod shelf 11. The pod 9 is temporarily stored in the rotatable pod shelf 11. Then, the pod 9 is transferred from the rotatable pod shelf 11 to the pod opener 14 (that is, one of the upper pod opener and the lower pod opener) by the pod transfer structure 15, and then transferred to the mounting table 21. Alternatively, the pod 9 may be directly transferred from the loading port 8 to the mounting table 21.

When the pod 9 is being transferred, the pair of wafer loading/unloading ports are closed by the opening/closing structure 22, and the transfer chamber 23 is filled with the clean air.

When an end surface of the pod 9 placed on the mounting table 21 is pressed against an opening edge of one of the pair of wafer loading/unloading ports of the front wall 17 of the sub-housing 16, the opening/closing structure 22 detaches the lid of the pod 9 and the wafer entrance of the pod 9 is opened.

When the pod 9 is opened by the pod opener 14 (that is, one of the upper pod opener and the lower pod opener), the wafer 18 is then taken out from the pod 9 by the wafer transfer structure 24, transferred to and aligned by a notch aligner (which is a notch aligning structure) (not shown). Then, by the wafer transfer structure 24, the wafer 18 is transferred (or loaded) into the standby space 27 provided in the rear region of the transfer chamber 23, and loaded (or charged) into the boat 26.

After the wafer 18 is charged into the boat 26, the wafer transfer structure 24 then returns to the pod 9 and transfers a subsequent wafer among the wafers 18 from the pod 9 into the boat 26.

While the wafer transfer structure 24 loads the wafer 18 into the boat 26 through the pod opener 14 (which is one of the upper pod opener and the lower pod opener), another pod 9 is transferred from the rotatable pod shelf 11 by the pod transfer structure 15 to the pod opener 14 (which is the other one of the upper pod opener and the lower pod opener), and the lid of the aforementioned another pod 9 is opened by the other one of the upper pod opener and the lower pod opener.

When a predetermined number of wafers including the wafer 18 are charged into the boat 26, the furnace opening of the process furnace 28 closed by the furnace opening shutter is opened by the furnace opening shutter. Subsequently, the boat 26 accommodating the predetermined number of wafers is elevated by the boat elevator 32 such that the boat 26 is loaded (inserted) into the process chamber 29.

After the boat 26 is loaded, the furnace opening is airtightly closed by the seal cap 34. Further, according to the present embodiments, at such a timing (that is, after the boat 26 is loaded), a purge step (also referred to as a “pre-purge step”) of replacing an atmosphere (inner atmosphere) of the process chamber 29 with the inert gas is performed.

The process chamber 29 is vacuum-exhausted by an exhaust controller 210 such that a pressure (inner pressure) of the process chamber 29 reaches and is maintained at a desired pressure (vacuum degree). In addition, the process chamber 29 is heated to a predetermined temperature by a temperature controller 207 such that a desired temperature distribution in the process chamber 29 is obtained.

Further, a process gas whose flow rate is controlled to a predetermined flow rate is supplied by a gas supply structure (which is a gas supplier), and the process gas comes into contact with a surface of the wafer 18 while flowing through the process chamber 29. Thereby, a predetermined processing such as a substrate processing described later is performed on the surface of the wafer 18. Further, the process gas after a reaction of the predetermined processing is exhausted from the process chamber 29 by a gas exhaust structure (which is a gas exhauster). In the present specification, the term “process gas” refers to a gas supplied into the process chamber 29. The same also applies to the following description.

After a predetermined process time has elapsed, the inert gas is supplied by the gas supply structure, the inner atmosphere of the process chamber 29 is replaced with the inert gas, and the inner pressure of the process chamber 29 is returned to the normal pressure (after-purge step). Then, the boat 26 is lowered by the boat elevator 32 through the seal cap 34. In the present specification, the term “process time” refers to a time duration of continuously performing a process related thereto. The same also applies to the following description.

After the wafer 18 is processed, the wafer 18 and the pod 9 are transferred (unloaded) out of the housing 2 in an order reverse to that of loading the wafer 18 and the pod 9 into the housing 2 described above. Then, an unprocessed wafer among the wafers 18 is further loaded into the boat 26, and a batch processing for the wafer 18 is performed one or more times.

According to the present embodiments, as shown in FIGS. 1 and 2, the substrate processing apparatus 1 includes a controller 100, and the controller 100 is configured to control the substrate processing apparatus 1. The controller 100 may be provided (embedded) in the substrate processing apparatus 1, or may be provided outside the substrate processing apparatus 1 in a manner accessible thereto. In the following, a case where the controller 100 according to the present embodiments is applied to the substrate processing apparatus 1 will be described. However, the controller 100 may control an apparatus other than the substrate processing apparatus 1.

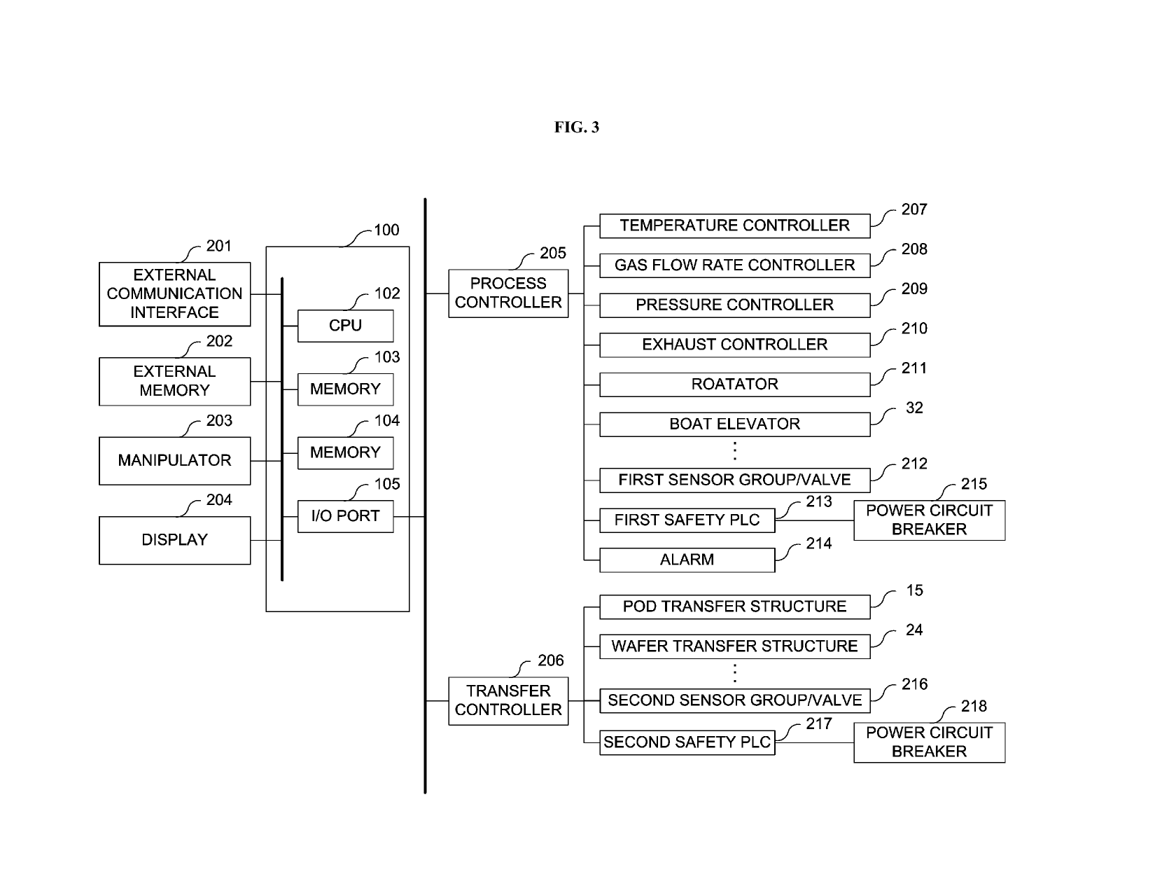

Subsequently, with reference to FIG. 3, a configuration of a control system of the substrate processing apparatus 1 according to the present embodiments will be described. FIG. 3 is a block diagram schematically illustrating an example of a functional configuration of the substrate processing apparatus 1 according to the present embodiments.

As shown in FIG. 3, the substrate processing apparatus 1 includes the controller (which is a main controller or a primary controller) 100, an external communication interface 201, an external memory 202, the manipulator 203, the display 204, the process controller 205 and a transfer controller 206.

The controller 100 is configured as a computer including a CPU (Central Processing Unit) 102, a memory 103, a memory 104 serving as a storage and an I/O port (input/output port) (also simply referred to as an “I/O”) 105. For example, the controller 100 is electrically connected to a network such as the Internet, a LAN (Local Area Network) and a WAN (Wide Area Network) by using the external communication interface 201, and is configured to be capable of communicating with external apparatuses via the network.

The process controller 205 and the transfer controller 206 are connected to the controller 100 via the I/O 105.

The controller 100 is connected to an external host computer (not shown) via the external communication interface 201. Therefore, even when the substrate processing apparatus 1 is installed in a clean room, the host computer can be disposed at a location such as an office outside the clean room. In addition, the external memory 202 (which serves as a mounting structure on which a recording medium such as a USB (Universal Serial Bus) memory is installed or removed) is connected to the controller 100.

The display 204 is a display structure (not shown) such as a liquid crystal display panel, which displays a screen. In addition, the manipulator 203 performs an input operation using an input device (not shown) such as a keyboard configured to input an operation input. In addition, when a touch panel is used, for example, the manipulator 203 and the display 204 may be configured as an integrated structure. According to the present embodiments, the subsidiary operation panel 50 is used as the manipulator 203 and the display 204.

The display 204 displays the screen to be used to check a state of a substrate processing system controlled by the process controller 205 and a state of a substrate transfer system controlled by the transfer controller 206. In addition, the display 204 can display, on the screen, various operation buttons serving as an input interface through which an operation instruction can be input to the substrate processing system and the substrate transfer system.

The process controller 205 is connected to the substrate processing system of the substrate processing apparatus 1. For example, the substrate processing system may include the temperature controller 207, the gas flow rate controller 208, a pressure controller 209, the exhaust controller 210, a rotator (which is a rotating structure) 211, the boat elevator 32, the first sensor group and a valve related thereto (hereinafter, the first sensor group and the valve related thereto may also be referred to as a “first sensor group/valve 212”), a first safety PLC 213 and an alarm (that is, an alarm device) 214. The first sensor group/valve 212 may include the sensors 53a to 53f as well as the sensors and the valves provided in the gas boxes 47 and 49, the process furnace 28 and the standby space 27. The process controller 205 is configured to control each of the temperature controller 207, the gas flow rate controller 208, the pressure controller 209, the exhaust controller 210, the rotator 211, the boat elevator 32, the alarm 214 and the like. For example, the alarm 214 is a buzzer configured to output a warning sound or a rotating light. The process controller 205 is configured to transmit the detection signals from the first sensor group/valve 212 to the CPU 102 via the I/O 105. Each of the temperature controller 207, the gas flow rate controller 208, the pressure controller 209, the exhaust controller 210 and the first safety PLC 213 constitutes a sub-controller, and is electrically connected to the process controller 205. In addition, the process controller 205 and each sub-controller (that is, the temperature controller 207, the gas flow rate controller 208, the pressure controller 209, the exhaust controller 210 and the first safety PLC 213) may be provided separately, or the process controller 205 and each sub-controller may be integrated into a single structure. A power circuit breaker 215 is connected to the first safety PLC 213.

The transfer controller 206 is connected to the substrate transfer system of the substrate processing apparatus 1. For example, the substrate transfer system may include the pod transfer structure 15, the wafer transfer structure 24, a second sensor group and a valve related thereto (hereinafter, the second sensor group and the valve related thereto may also be referred to as a “second sensor group/valve 216”) and a second safety PLC 217. The second sensor group/valve 216 may include the sensors and the valves provided in the transfer chamber 23 and the like, as well as those in the gas boxes 47 and 49, the process furnace 28 and the standby space 27. The transfer controller 206 is configured to control each of the pod transfer structure 15 (which is provided with a plurality of servo motors), the wafer transfer structure 24 and the like. The transfer controller 206 is also configured to transmit the detection signals from the second sensor group/valve 216 to the CPU 102 via the I/O 105. The second safety PLC 217 constitutes a sub-controller, and is electrically connected to the transfer controller 206. In addition, the transfer controller 206 and the sub-controller (that is, the second safety PLC 217) may be provided separately, or the transfer controller 206 and the sub-controller (that is, the second safety PLC 217) may be integrated into a single structure. A power circuit breaker 218 is connected to the second safety PLC 217.

The first safety PLC 213 and the second safety PLC 217 are sequencers conforming to a standard such as ISO 13849-1 and IEC 61508, and are used as safety interlock structures implementing a logic capable of determining whether or not a condition for each of the ILKs is satisfied. The first safety PLC 213 is configured to output a result of calculation of each definition equation to the alarm 214, the display 204, the power circuit breaker 215 and the like of the substrate processing apparatus 1 based on the detection signals from the first sensor group/valve 212. The second safety PLC 217 is configured to output a result of calculation of each definition equation to the display 204, the power circuit breaker 218, the pod transfer structure 15, the wafer transfer structure 24 and the like based on the detection signals from the second sensor group/valve 216. The first safety PLC 213, the second safety PLC 217 and the controller 100 are implemented by hardware configurations independent of each other. In addition, the first safety PLC 213 and the second safety PLC 217 may be interconnected or may be integrated into a single PLC. The first safety PLC 213 and the second safety PLC 217 are described by a ladder logic.

In other words, the controller 100 is configured to receive the detection signals from the first sensor group/valve 212 or the second sensor group/valve 216 through the process controller 205 or the transfer controller 206 via the I/O 105, and is provided with an interlock determination program capable of determining whether the condition for each of the ILKs is satisfied. Thereby, the controller 100 is configured to make the same determination as the first safety PLC 213 and the second safety PLC 217. As a result, even when a malfunction (or failure) occurs in the controller 100, the first safety PLC 213 or the second safety PLC 217, it is possible to activate the ILK.

According to the present embodiments, each of the controller 100, the process controller 205 and the transfer controller 206 may be embodied by a general computer system instead of a dedicated computer system. For example, by installing in the general computer system a program for executing the predetermined processing described above from a predetermined recording medium such as a CD-ROM and a USB memory storing the program, each controller described above may be provided to perform the predetermined processing.

For example, a method of supplying the program can be appropriately selected. Instead of or in addition to being supplied through the predetermined recording medium as described above, for example, the program may be provided through a communication network.

A recipe file such as a recipe in which process conditions of the substrate processing are defined may be obtained from another apparatus via the external communication interface 201, or may be obtained from a recording medium such as a USB via the external memory 202.

Further, for example, the memory 104 is configured as an auxiliary memory such as a hard disk drive (HDD), a solid state drive (SSD) and a flash memory. In the memory 104, a recording medium in which an operation program executed by the CPU 102 is recorded or a recording medium in which the recipe file is recorded may be stored. The operation program stored in the memory 104 is transferred to the memory 103 of the controller 100 and executed when the substrate processing apparatus 1 is started up, for example.

In addition, in the memory 104, a display processing program capable of performing a process for displaying an occurrence of the ILK according to the present embodiments is stored. For example, the display processing program is installed in advance in the substrate processing apparatus 1. The display processing program may be implemented by appropriately installing the display processing program (which may be recorded on a non-volatile recording medium or distributed via a network) in the substrate processing apparatus 1. For example, as the non-volatile recording medium, a component such as a CD-ROM, a magneto-optical disk, a HDD, a DVD-ROM, a flash memory, a memory card and a USB may be used.

In the memory 104, an interlock condition table (in which a condition under which a preset ILK is established is associated with each of the plurality of ILKs) is also stored. In addition, in the memory 104, image data of an image indicating a structure of the substrate processing apparatus 1 and image data of information indicating the plurality of ILKs are also stored.

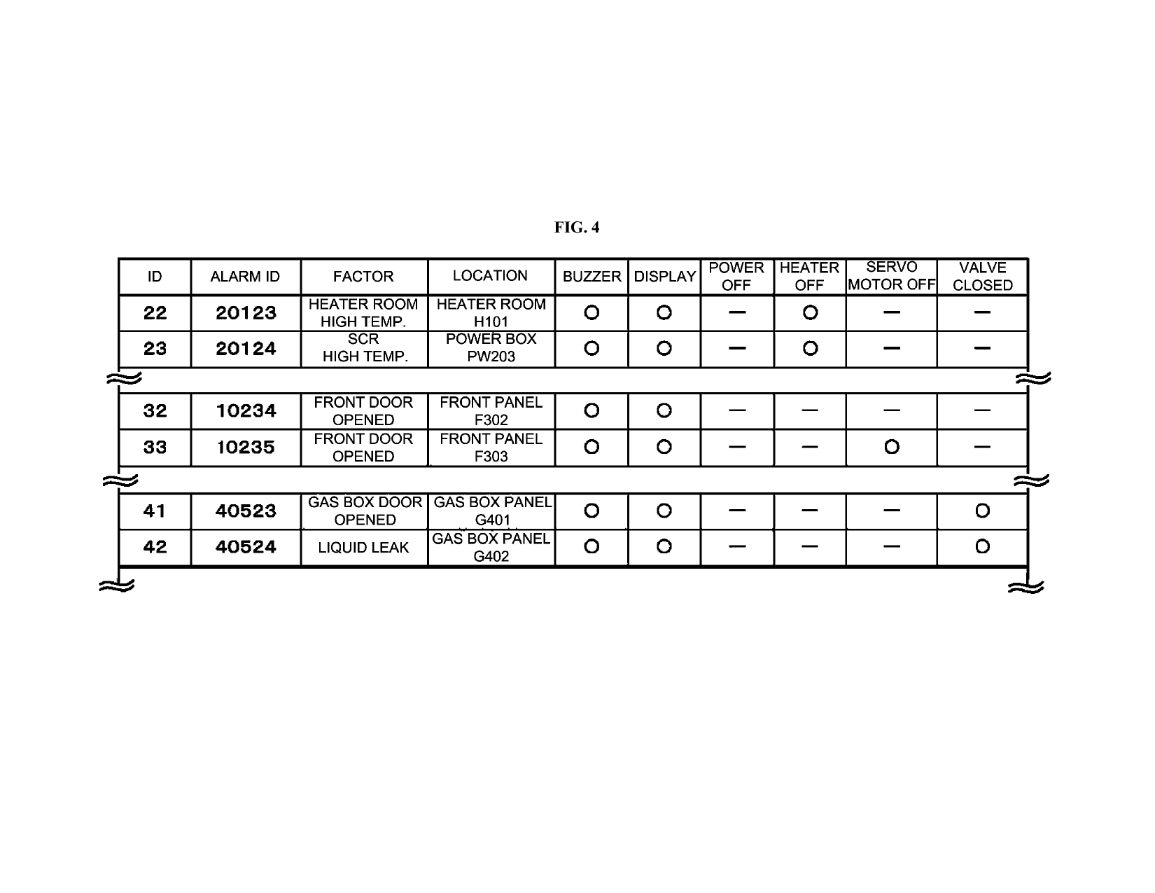

FIG. 4 is a diagram schematically illustrating an example of the interlock condition table stored in the memory 104. As shown in FIG. 4, in the memory 104, the condition under which the preset ILK is established is stored for each of the plurality of ILKs. Specifically, an ID (which is an identification number indicating contents of the ILK), an alarm ID (which identifies contents of an alarm), one factor establishing the ILK or one factor preventing the ILK from being established, a location where the ILK occurs and an output content of the ILK are stored in association with one another. The location where the ILK occurs is based on the detection signals from the first sensor group/valve 212 or the second sensor group/valve 216. The first sensor group/valve 212 or the second sensor group/valve 216 may serve as the one factor establishing the ILK or one factor preventing the ILK from being established. In addition, when there are a plurality of factors establishing the ILK, a combination of Boolean algebra and a timer processing may be used to define its cause. The condition under which the preset ILK is established may be switched depending on a state of the substrate processing apparatus 1. For example, the state of the substrate processing apparatus 1 may include a state in which the substrate processing is being performed, a state in which a cleaning process is being performed, a state in which an idling process is being performed and a state in which a maintenance process is being performed.

When the factor of the ILK exists in the substrate processing system, a power control system ILK is set as the output content of the ILK. For example, the power control system ILK is set to sound the buzzer, display on the display 204, shut off a power supply to the entire apparatus (that is, the entire substrate processing apparatus 1) or shut off a power supply to each component connected to the process controller 205. When the factor of the ILK exists in the substrate transfer system, a transfer system ILK is set as the output content of the ILK. For example, the transfer system ILK is set to sound the buzzer, display on the display 204, or shut off a power supply to each component connected to the transfer controller 206. When the factor of the ILK is the gas leak, a gas system ILK is set as the output content of the ILK. For example, the gas system ILK is set to sound the buzzer, display on the display 204, or close the corresponding valve or the entirety of the valves.

In the memory 104, the image data of the image indicating the structure of the substrate processing apparatus 1 and an interlock display position table (which retains or stores) positions in the image indicating the structure of the substrate processing apparatus 1 corresponding to each module corresponding to each factor establishing the ILK or each factor preventing the ILK from being established) are also stored. The interlock display position table is further configured to store a substantial factor (also referred to as an “essential factor”) which is not a factor directly establishing the ILK but is a fundamental factor, in association with the ID and the like. In other words, the interlock display position table may also be referred to as a “substantial factor table” configured to store (or retain) the substantial factor establishing the ILK as a single factor establishing the ILK, for each of the plurality of ILKs.

In such an example, the substantial factor may include a manual valve that is not detected by the first sensor group/valve 212 or the second sensor group/valve 216. That is, even when the first sensor group/valve 212 or the second sensor group/valve 216 fails to detect the location corresponding to the factor of the ILK, it is possible to identify the location causing the ILK.

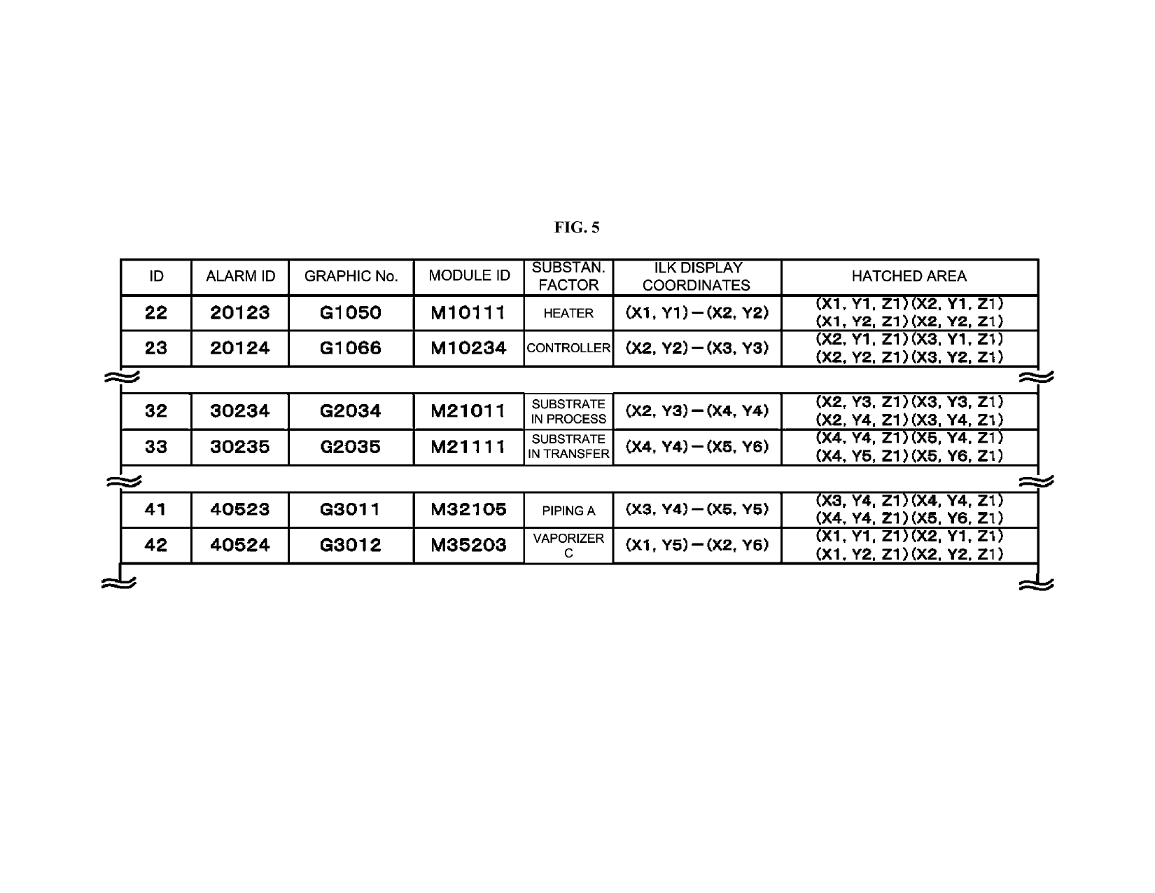

FIG. 5 is a diagram schematically illustrating an example of the interlock display position table stored in the memory 104. As shown in FIG. 5, in the memory 104, the interlock display position table (which retains the positions in the image indicating the structure of the substrate processing apparatus 1 corresponding to each module corresponding to each factor establishing the ILK or each factor preventing the ILK from being established) is stored. Specifically, the ID, the alarm ID, a graphic number of the image data of the image indicating the structure of the substrate processing apparatus 1 used when displaying on the display 204, a module ID (which identifies the module corresponding to the factor establishing the ILK or the module corresponding to the factor preventing the ILK from being established), the actual factor of the ILK, display coordinates of the information indicating the ILK, and coordinates indicating a hatched area of the module corresponding to the factor establishing the ILK or the module corresponding to the factor preventing the ILK from being established are stored in association with one another.

According to the present embodiments, as the image indicating the structure of the substrate processing apparatus 1, a projected or perspective image of a three-dimensional model of the substrate processing apparatus 1 from a predetermined viewpoint may be used, or a photograph or other image of an apparatus whose configuration is substantially the same as that of the substrate processing apparatus 1 may be used.

Under a control of the controller 100, the display 204 is capable of graphically displaying, in a recognizable manner, a module corresponding to one factor establishing the ILK in a case where the ILK among the plurality of ILKs is established or a module corresponding to one factor preventing the ILK from being established in a case where the ILK occurs if one more physical state satisfies a condition, on the image indicating the structure of the substrate processing apparatus 1.

In addition, under the control of the controller 100, the display 204 is capable of displaying the information indicating the ILK including at least one among the occurrence of the ILK, the location where the ILK occurs, the ID, an event of the ILK and the factor of the ILK, on the image indicating the structure of the substrate processing apparatus 1 in a superimposed manner, at a position corresponding to the module corresponding to each factor. For example, as the information indicating the ILK, the image data may be used.

In other words, according to the present embodiments, the controller 100 functions as a display controller capable of controlling the display 204. In addition, the controller 100 stores the condition under which the preset ILK is established for each of the plurality of ILKs, and also functions as an interlock determination processor configured to determine whether or not the condition for each of the ILKs is satisfied based on the detection signals from the first sensor group/valve 212 and the second sensor group/valve 216. The controller 100 also functions as a preliminary detector (also referred to as a “backup detector”) configured to detect the module corresponding to the factor preventing the ILK from being established in a case where the ILK among the plurality of ILKs occurs if one more physical state satisfies the condition. In other words, the controller 100 may also be referred to as an “interlock system” capable of determining the ILK based on the detection signals from the sensors and the like, and capable of graphically displaying, in a recognizable manner, the module corresponding to one factor causing the ILK or the module corresponding to one factor preventing the ILK from being established, on the image indicating the structure of the substrate processing apparatus 1.

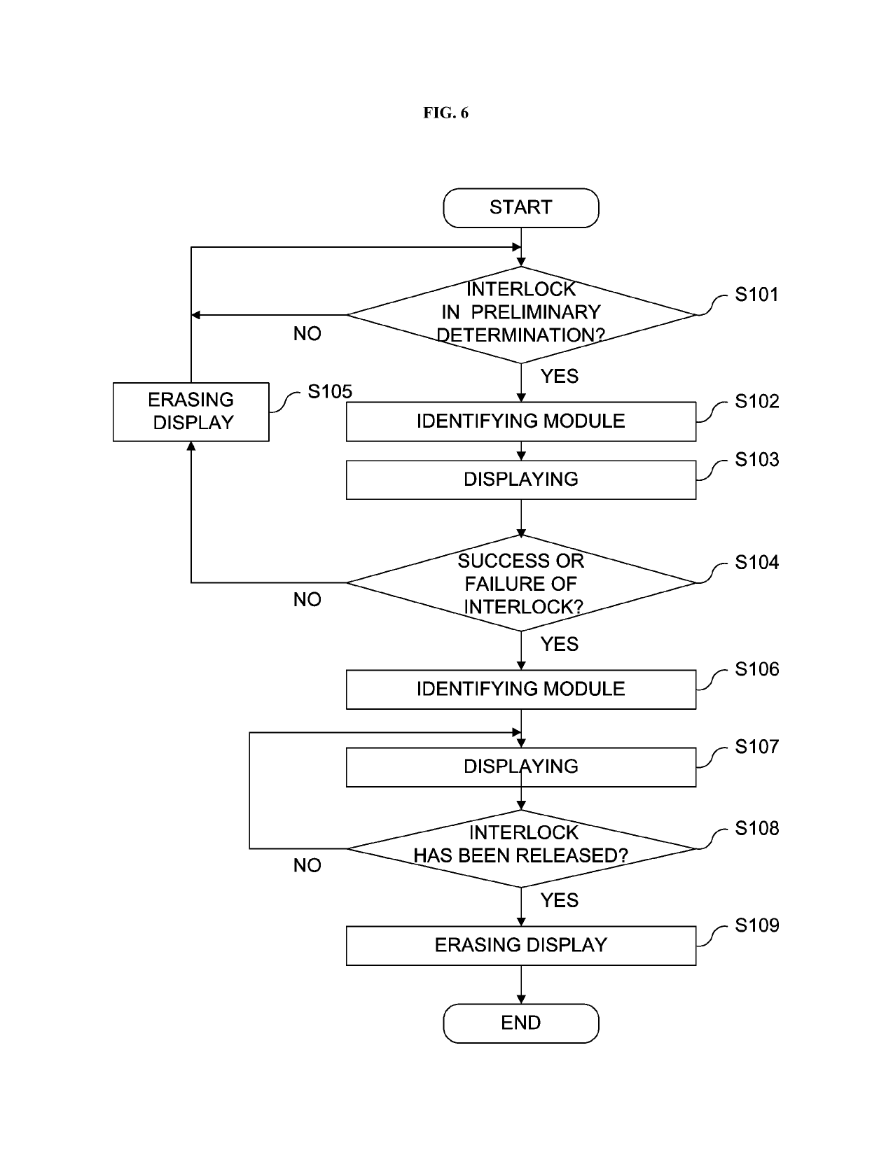

Subsequently, a display process of the ILK during operation of the substrate processing apparatus 1 will be described with reference to FIGS. 6 to 8.

In a step S101, the controller 100 detects the ILK in a preliminary determination using the first sensor group/valve 212 or the second sensor group/valve 216. Then, when the controller 100 determines that the ILK will be activated if one more physical state satisfies the condition based on the interlock condition table stored in the memory 104 (“YES” in the step S101), in a step S102, the controller 100 identifies the module corresponding to the factor preventing the ILK from being established.

Specifically, the first sensor group/valve 212 or the second sensor group/valve 216 respectively detects the physical state of the substrate processing apparatus 1, and outputs the detection signals to the CPU 102 through the process controller 205 or the transfer controller 206 via the I/O 105. When the controller 100 determines, based on the detection signals from the first sensor group/valve 212 or the second sensor group/valve 216, that the ILK will be activated if one more physical state satisfies the condition, then in the step S102, the controller 100 identifies the module corresponding to one factor preventing the ILK from being established based on the detection signals.

Then, in a step S103, the controller 100 graphically displays on the display 204, when detecting an unestablished ILK, a module corresponding to one factor preventing the ILK (unestablished ILK) from being established such that the module can be recognized in the image indicating the structure of the substrate processing apparatus 1. In other words, the controller 100 graphically displays the module identified in the step S102 such that the module can be recognized in the image indicating the structure of the substrate processing apparatus 1. As a result, it is possible for the worker to recognize an operation to activate the ILK before the ILK is actually activated. Thereby, it is also possible to prevent an erroneous operation activating the ILK.

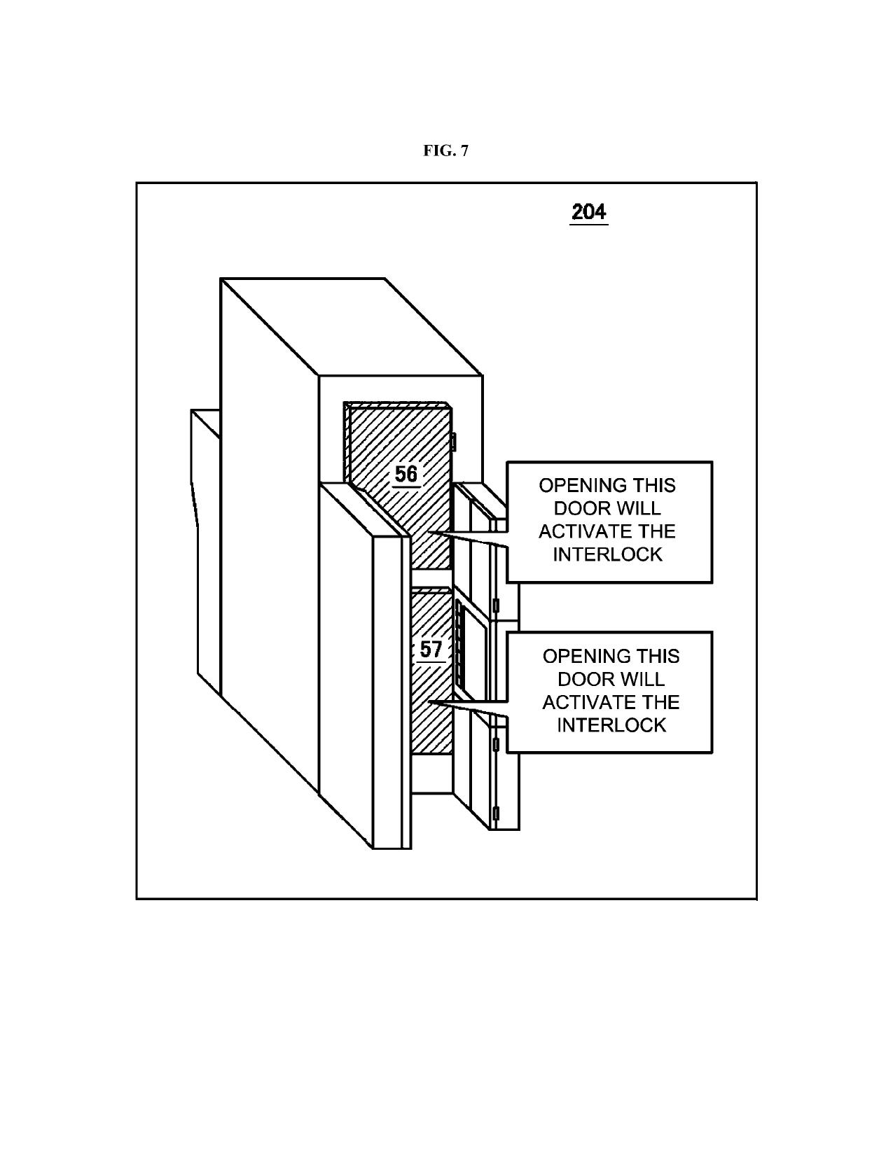

Specifically, for example, in a case where the ILK is activated if opening the doors 56 and 57, as shown in FIG. 7, the display 204 displays an image of a rear structure of the substrate processing apparatus 1, clearly indicating the location where the ILK will occur. For example, the doors 56 and 57 of the substrate processing apparatus 1 on a rear portion thereof are displayed in a hatched manner based on the interlock display position table stored in the memory 104, and the information indicating the ILK, such as “Opening this door will activate the interlock”, is displayed in a superimposed manner. In a manner described above, to prevent the ILK from being activated by accidentally opening the door, a warning (also referred to as a “caution display”) is displayed before the ILK is activated to prevent the ILK from being activated.

Then, in a step S104, the controller 100 determines whether or not the condition for each of the ILKs is satisfied based on the interlock condition table stored in the memory 104. When one ILK among the plurality of ILKs is established (“YES” in the step S104), the controller 100 identifies the module corresponding to the factor that established the ILK in a step S106. In such an operation, the controller 100 also outputs information based on the factor via the process controller 205 or the transfer controller 206, based on the interlock condition table. Specifically, the controller 100 activates the buzzer, shuts off the power to each component or the entirety of the apparatus, closes the corresponding valve, or closes the entirety of the valves.

When the controller 100 determines that none of the plurality of ILKs is established (“NO” in the step S104), in a step S105, the controller 100 erases (or clears) the display created in the step S103. Then, the step S101 is performed again.

In a step S107, the controller 100 graphically displays the module identified in the step S106 in a recognizable manner in the image indicating the structure of the substrate processing apparatus 1.

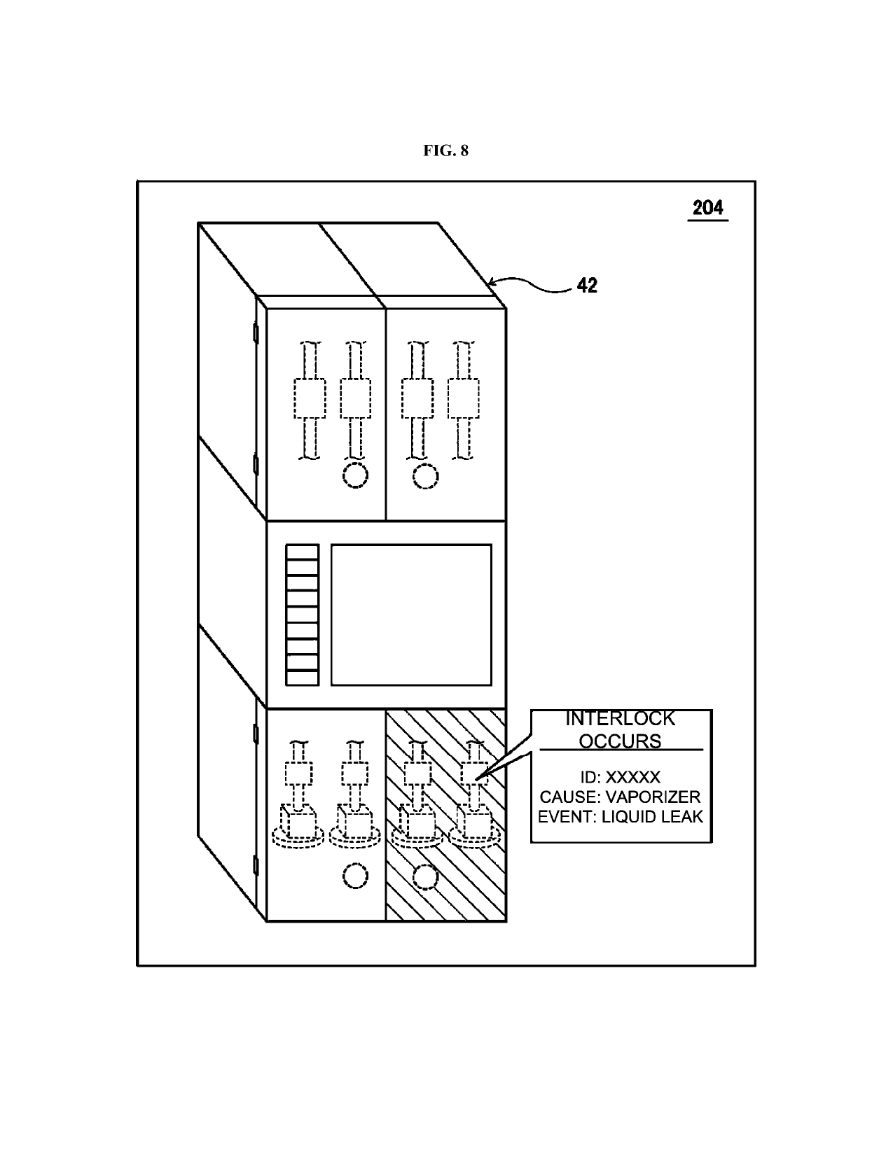

Specifically, for example, when the liquid leak is detected by the liquid leak sensor, the ID, the alarm ID and the location where the ILK occurs are identified using the interlock condition table stored in the memory 104, and the buzzer and the ILK that closes the corresponding valve are activated. Then, using the interlock display position table stored in the memory 104 based on the ID or alarm ID identified as described above, it is possible to identify that the actual factor (actual cause) of the liquid leak is the vaporizer, and it is possible to identify display coordinates of the ILK, the display coordinates of the information indicating the ILK, and the coordinates indicating the hatched area of the module corresponding to the factor that established the ILK. In addition, as shown in FIG. 8, the module in the utility structure 42 corresponding to the factor that established the ILK is displayed in a hatched manner based on the display coordinates of the ILK and the coordinates indicating the hatched area. The information indicating the ILK, such as the occurrence of the ILK, the ID, the actual factor (actual cause) of the ILK and the event of the ILK, is displayed in a superimposed manner on the image of the module (which is hatched) in the utility structure 42.

In a manner described above, by graphically displaying the location where the ILK occurs on the image indicating the structure of the substrate processing apparatus 1 and displaying the information indicating the ILK (such as the occurrence of the ILK, the factor of the ILK and the event of the ILK) on the image indicating the structure of the substrate processing apparatus 1 in a superimposed manner, it is possible to easily identify the location where the ILK occurs and the actual factor of the ILK. In addition, it is possible to shorten a downtime of the apparatus. In FIG. 8, an inner structure of the utility structure 42 is illustrated simply. However, as an image indicating a structure of the utility structure 42, a projected or perspective image of a three-dimensional model of the utility structure 42 from a predetermined viewpoint may be used, or a photograph or other image of an apparatus whose configuration is substantially the same as that of the utility structure 42 may be used.

Then, in a step S108, the controller 100 determines whether the ILK has been released. That is, after completing measures such as replacing the location (that is, the actual factor of the ILK), the worker releases the ILK by pressing a reset switch. When the controller 100 determines, in the step S108, that the ILK has not been released, the step S107 is performed again.

In the step S108, when the controller 100 receives a release operation for the ILK and determines that the ILK has been released, the controller 100 erases (or clears) the display of the ILK (which is released) in a step S109 and terminates the display process for the ILK. The release operation for the ILK may be performed by using a screen displaying a list of the ID and the alarm ID, or may be performed by clicking on the module with the information indicating the ILK superimposed on the image indicating the structure of the substrate processing apparatus 1 displayed on the display 204.

In a manner described above, by displaying the location where the ILK is occurring or the location where the ILK will occur on an image indicating a structure of the apparatus (that is, the substrate processing apparatus 1), it is possible for the worker to easily identify the location where the ILK is occurring or the location where the ILK will occur. In addition, by displaying the information indicating the ILK, it is possible for the worker to easily investigate the cause of the ILK, and it is also possible to shorten the downtime of the apparatus. In addition, even when a plurality of ILKs occur, it is possible for the worker to infer a common substantial factor based on the proximity of locations where the plurality of ILKs occur.

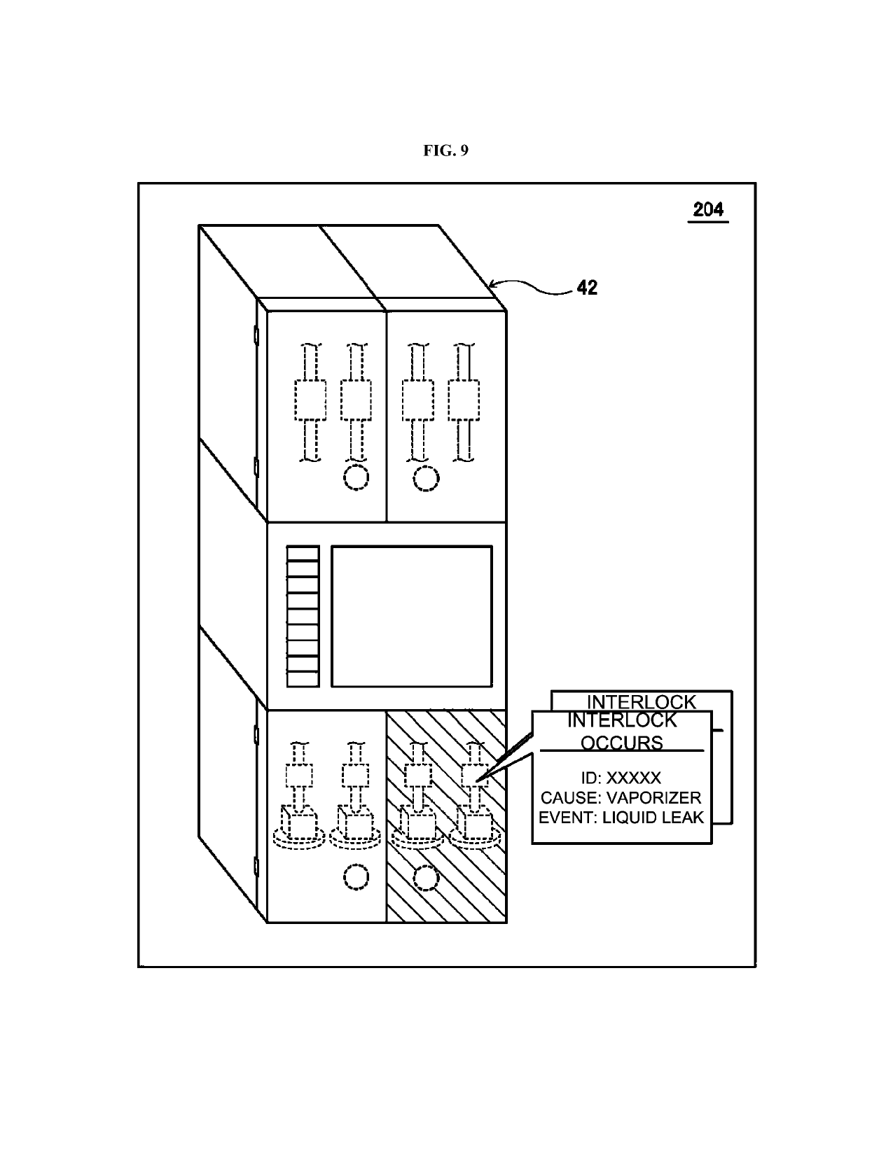

FIG. 9 is a diagram schematically illustrating a modified example of a display screen for the ILK on the display 204.

FIG. 9 is a diagram schematically illustrating a case where a plurality of ILKs occur in the same module of the substrate processing apparatus 1.

When a succeeding ILK to be displayed occurs before a preceding ILK being displayed on display screen is released, the controller 100 controls the display 204 to display the information indicating the preceding and the information indicating succeeding ILKs in a superimposed manner at positions corresponding to the modules associated with the respective factors therefor. Further, when the positions corresponding to the modules associated with the respective factors are close to each other in the image indicating the structure of the substrate processing apparatus 1, the controller 100 superimposes the display of the information indicating the preceding ILK and the display of the information indicating the succeeding ILK such that the display of one information is hidden by the display of the other information.

According to the present modified example, it is possible to obtain substantially the same effects as in the embodiments mentioned above. In addition, according to the present modified example, it is possible for the worker to infer a common substantial factor based on the proximity of locations (where the plurality of ILKs occur) displayed on the display 204. In addition, since the displays (that is, the information indicating the preceding and succeeding ILKs) are displayed in a superimposed manner, the displays are consolidated to be easier to view. In addition, it is possible for the worker to easily identify the locations where the ILKs occur.

The configuration of the substrate processing apparatus 1 and a display control on the display 204 described in the embodiments and the modified example mentioned above are merely examples, and may be changed depending on the situation, without departing from the scope of the technique of the present disclosure.

For example, the embodiments mentioned above are described by way of an example in which the utility structure 42 is divided into a plurality of modules (portions), and the module corresponding to one factor establishing the ILK or one factor preventing the ILK from being established is graphically displayed on the display 204 such that the module can be recognized in the image indicating the structure of the substrate processing apparatus 1. However, the present embodiments are not limited thereto. For example, the exhaust structure 43 or another component constituting the substrate processing apparatus 1 may be divided into a plurality of modules, and a module corresponding to one factor establishing the ILK or one factor preventing the ILK from being established may be graphically displayed on the display 204 such that the module can be recognized in the image indicating the structure of the substrate processing apparatus 1.

For example, the embodiments mentioned above are described by way of an example in which the controller 100 is used as the interlock determination processor and the display controller. However, the present embodiments are not limited thereto. For example, the interlock determination processor and the display controller may be provided in the host computer shared by a plurality of apparatuses. In such a case, the host computer may perform a control by: receiving sensor information and the information indicating the ILK from the substrate processing apparatus 1; determining whether or not the ILK is established; and displaying the information on the display 204. For example, as the display 204, a mobile device such as a tablet computer may be used.

For example, the embodiments mentioned above are described by way of an example in which the module corresponding to one factor establishing the ILK or one factor preventing the ILK from being established is graphically displayed on the display 204 such that the module can be recognized in the image indicating the structure of the substrate processing apparatus 1. However, the present embodiments are not limited thereto. For example, an augmented reality apparatus may be used. In such a case, the image indicating the ILK may be displayed in a superimposed manner on a real image of the substrate processing apparatus 1 such that the image can be visually recognized by a human.

Further, the process flow described in the embodiments mentioned above is merely an example, and a redundant step may be deleted, a new step may be added or process procedures may be changed, without departing from the scope of the technique of the present disclosure.

For example, the embodiments mentioned above are described by way of an example in which the processing according to the embodiments is implemented by a software configuration that uses the computer to execute the program. However, the technique of the present disclosure is not limited thereto. For example, the technique of the present disclosure may also be applied to a hardware configuration capable of performing the processing, or may also be applied to a combination of a hardware configuration and a software configuration capable of performing the processing.

For example, the technique of the present disclosure may be applied to not only a substrate processing apparatus of manufacturing a semiconductor device but also an apparatus capable of processing a glass substrate such as an LCD (Liquid Crystal Display) manufacturing apparatus, or other substrate processing apparatus. The contents of the substrate processing may include not only a film forming process of forming a film such as a CVD (Chemical Vapor Deposition) film, a PVD (Physical Vapor Deposition) film, an epitaxial growth film, an oxide film, a nitride film and a metal-containing film, but also a process such as an annealing process, an oxidation process, a diffusion process, an etching process, an exposure process, a photolithography process, a coating process, a molding process, a developing process, a dicing process, a wire bonding process and an inspection process.

For example, the embodiments mentioned above are described by way of an example in which the vertical type substrate processing apparatus (also referred to as a “batch type substrate processing apparatus”) capable of simultaneously processing a plurality of substrates is used to process the substrate. However, the technique of the present disclosure is not limited thereto. For example, the technique of the present disclosure may be preferably applied when a single wafer type substrate processing apparatus capable of simultaneously processing one or several substrates at a time is used to process the substrate. For example, the embodiments mentioned above are described by way of an example in which a substrate processing apparatus including a hot wall type process furnace is used to process the substrate. However, the technique of the present disclosure is not limited thereto. For example, the technique of the present disclosure may be preferably applied when a substrate processing apparatus including a cold wall type process furnace is used to process the substrate.

The process procedures and the process conditions of each process using the substrate processing apparatuses exemplified above may be substantially the same as those of the embodiments or the modified examples described above. Even in such a case, it is possible to obtain substantially the same effects as in the embodiments or the modified examples described above.

In addition, the embodiments and the modified examples mentioned above may be appropriately combined. The process procedures and the process conditions of each combination thereof may be substantially the same as those of the embodiments mentioned above or the modified examples mentioned above.

According to some embodiments of the present disclosure, it is possible to easily identify a location causing an interlock or a location likely to cause the interlock.

What is claimed is:

1. An interlock system comprising:
detectors respectively provided in a plurality of modules constituting a substrate processing apparatus, configured to detect physical states of the substrate processing apparatus and configured to output detection signals indicating the physical states;
an interlock determination processor configured to store preset interlock conditions establishing a plurality of interlocks, respectively, and configured to determine whether or not each of the plurality of interlocks is established based on the detection signals from the detectors; and
a display controller configured to be capable of graphically displaying, on a display, a module corresponding to a first factor establishing an interlock among the plurality of interlocks in a case where the interlock is established or corresponding to a second factor preventing the interlock from being established in a case where the interlock occurs if a physical state among the physical states satisfies a condition among the interlock conditions corresponding thereto, such that the module is recognizable on an image indicating a structure of the substrate processing apparatus.

2. The interlock system of claim 1, further comprising:
a memory configured to store image data of the image indicating the structure of the substrate processing apparatus and a display position table retaining positions in the image indicating the structure of the substrate processing apparatus corresponding to a module corresponding to each factor establishing each interlock or corresponding to each factor preventing each interlock from being established,
wherein the display controller is further configured to control a display of information indicating the interlock to be superimposed on the image indicating the structure of the substrate processing apparatus at a position corresponding to the module corresponding to each factor.

3. The interlock system of claim 2, wherein the information indicating the interlock is image data.

4. The interlock system of claim 2, wherein the memory is further configured to store a substantial factor table retaining, for each of the plurality of interlocks, a substantial factor establishing each interlock as a single factor establishing each interlock.

5. The interlock system of claim 1, further comprising
a preliminary detector configured to detect the module corresponding to the second factor preventing the interlock from being established in the case where the interlock among the plurality of interlocks occurs if the physical state satisfies the condition,
wherein the display controller is further configured to be capable of graphically displaying, on the display, in association with the interlock detected as inactivated by the preliminary detector, the module corresponding to the second factor preventing the interlock from being established such that the module is capable of being recognized on the image indicating the structure of the substrate processing apparatus.

6. The interlock system of claim 1, wherein the plurality of modules are formed by dividing at least one of a utility structure or an exhaust structure of the substrate processing apparatus into a plurality of portions.

7. The interlock system of claim 1, wherein the image indicating the structure of the substrate processing apparatus comprises at least one among a projected or perspective image of a three-dimensional model of the substrate processing apparatus from a predetermined viewpoint and a photograph of an apparatus whose configuration is substantially same as that of the substrate processing apparatus.

8. The interlock system of claim 1, wherein the display comprises an augmented reality apparatus by which an image indicating the interlock is displayed on a real image of the substrate processing apparatus in a superimposed manner such that the image is capable of being visually recognized by a human.

9. The interlock system of claim 1, further comprising:
a safety interlock structure configured to implement a logic capable of determining whether or not each of the interlock conditions for the plurality of interlocks is satisfied, and further configured to output a result of calculation of each definition equation based on the detection signals from the detectors to at least one among an alarm, the display controller, a power circuit breaker, a container transfer structure, a transfer structure and a valve, which are provided in the substrate processing apparatus,
wherein the interlock determination processor is implemented by a controller configured to execute a program that makes same determination as the safety interlock structure.

10. The interlock system of claim 1, wherein the display controller is further configured to, in a case where a succeeding interlock to be displayed is established before a preceding interlock being displayed on the display is released, display information indicating the preceding interlock and information indicating the succeeding interlock in a superimposed manner at positions corresponding to the modules corresponding to the respective factors therefor, and further configured to, when the positions corresponding to the modules associated with the respective factors are close to each other in the image indicating the structure of the substrate processing apparatus, display the information indicating the preceding interlock and the information indicating the succeeding interlock in the superimposed manner such that a display of one of the information is hidden by a display of the other of the information.

11. The interlock system of claim 9, wherein the safety interlock structure and the controller are implemented by hardware configurations independent of each other.

12. A substrate processing apparatus comprising:
the interlock system of claim 1; and
the plurality of modules.

13. An interlock display method comprising:
(a) detecting physical states of a substrate processing apparatus using detectors respectively provided in a plurality of modules constituting the substrate processing apparatus, and outputting detection signals indicating the physical states;
(b) storing preset interlock conditions establishing a plurality of interlocks, respectively, and determining whether or not each of the plurality of interlocks is established based on the detection signals from the detectors; and
(c) graphically displaying, on a display, a module corresponding to a first factor establishing an interlock among the plurality of the interlocks in a case where the interlock is established or a module corresponding to a second factor preventing the interlock from being established in a case where the interlock occurs if a physical state among the physical states satisfies a condition among the interlock conditions corresponding thereto, such that the module is recognizable on an image indicating a structure of the substrate processing apparatus.

14. A method of manufacturing a semiconductor device, comprising:
the method of claim 13; and
processing a substrate.

15. A non-transitory computer-readable recording medium storing a program that causes, by a computer, a substrate processing apparatus to perform a process comprising the method of claim 13.
